(19) United States
(12) Patent Application Publication
(10) Pub. No.: US 2025/0107367 A1
(43) Pub. Date: Mar. 27, 2025

(54) DISPLAY SUBSTRATE AND DISPLAY DEVICE

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Hongjun ZHOU, Beijing (CN); Yudiao CHENG, Beijing (CN); Fengli JI, Beijing (CN)

(73) Assignees: CHENGDU BOE OPTOELECTRONICS TECHNOLOGY CO., LTD., Sichuan (CN); BOE TECHNOLOGY GROUP CO., LTD., Beijing (CN)

(21) Appl. No.: 18/832,933

(22) PCT Filed: Oct. 26, 2023
(86) PCT No.: PCT/CN2023/126820

§ 371 Date: Jul. 25, 2024

(30) Foreign Application Priority Data
Nov. 30, 2022 (CN) 202211518953.8

(51) Int. Cl. H10K 59/131; H10K 59/121; H10K 59/65; H10K 59/88

(52) U.S. Cl. CPC H10K 59/131; H10K 59/121; H10K 59/65; H10K 59/88

(57) ABSTRACT

A display substrate includes: a substrate, light-emitting devices including first and second light-emitting devices, pixel circuits, data lines including first and second data lines, and control signal lines. The pixel circuits include first pixel circuits coupled to the first light-emitting devices and second pixel circuits coupled to the second light-emitting devices. A first data line includes a transfer signal line, and a first data sub-line and a second data sub-line coupled to the transfer signal line. The first data sub-line is coupled to first pixel circuits. A second data line and the second data sub-line are coupled to second pixel circuits. A first capacitance value of a parasitic capacitor between the first data line and a control signal line and a second capacitance value of a parasitic capacitor between the second data line and the control signal line have a difference less than or equal to 0.15 fF.

### CROSS-REFERENCE TO RELATED APPLICATIONS

This application is a national phase entry under 35 USC 371 of International Patent Application No. PCT/CN2023/126820, filed on Oct. 26, 2023, which claims priority to Chinese Patent Application No. 202211518953.8, filed on Nov. 30, 2022, which are incorporated herein by reference in their entirety.

### TECHNICAL FIELD

The present disclosure relates to the field of display technologies, and in particular, to a display substrate and a display device.

### BACKGROUND

In order to improve a visual effect of a display screen, it is necessary to increase a proportion of a display region of a display screen as much as possible, that is, to increase a screen-to-body ratio of the display screen. The display screen with the screen-to-body ratio of 100% or approximately 100% is generally referred to as a “full screen”.

Currently, the full-screen display device uses under-screen camera technology, that is, the camera is arranged below the display screen so that a region of the display screen corresponding to the camera also displays images, which avoids the front camera occupying the display region of the display screen, and in turn facilitates the screen-to-body ratio to approach or reach 100% to realize full screen display.

### SUMMARY

In an aspect, a display substrate is provided. The display substrate includes a substrate, a plurality of light-emitting devices, a plurality of pixel circuits, a plurality of data lines and a plurality of control signal lines. The substrate includes a display region and a peripheral region located on at least one side of the display region. The display region includes a light-transmissive display region and a main display region located on at least one side of the light-transmissive display region. The plurality of light-emitting devices include a plurality of first light-emitting devices and a plurality of second light-emitting devices; the plurality of first light-emitting devices are located in the light-transmissive display region, and the plurality of second light-emitting devices are located in the main display region. The plurality of pixel circuits are located in the main display region. The plurality of pixel circuits include a plurality of first pixel circuits and a plurality of second pixel circuits, the plurality of first pixel circuits are coupled to the plurality of first light-emitting devices through a plurality of conductive lines, the plurality of second pixel circuits are coupled to the plurality of second light-emitting devices, and the plurality of second pixel circuits are arranged between the first pixel circuits at intervals.

The plurality of data lines include a plurality of first data lines and a plurality of second data lines. A first data line includes a transfer signal line extending in a first direction, and a first data sub-line and a second data sub-line extending in a second direction. The transfer signal line is located between pixel circuits and is coupled to the first data sub-line and the second data sub-line, the second direction and the first direction intersecting; the first data sub-line is coupled to first pixel circuits, and a second data line and the second data sub-line are coupled to second pixel circuits. The plurality of control signal lines extend in the first direction, and the plurality of control signal lines are coupled to the plurality of first pixel circuits and the plurality of second pixel circuits. A parasitic capacitor between the first data line and a control signal line has a first capacitance value, a parasitic capacitor between the second data line and the control signal line has a second capacitance value, and a difference between the first capacitance value and the second capacitance value is less than or equal to 0.15 fF.

In some embodiments, the first capacitance value and the second capacitance value are substantially equal.

In some embodiments, the main display region further includes a plurality of sub-pixel regions. The plurality of pixel circuits are respectively located in the plurality of sub-pixel regions; the plurality of sub-pixel regions include first sub-pixel regions and second sub-pixel regions; a first sub-pixel region includes a transfer structure; and the second data sub-line is coupled to the transfer signal line through the transfer structure.

In some embodiments, a second sub-pixel region further includes a dummy transfer structure; the dummy transfer structure is coupled to a part of a data line in the second sub-pixel region and is separated from the transfer signal line.

In some embodiments, an area of an orthographic projection of the dummy transfer structure on the substrate is less than or substantially equal to an area of an orthographic projection of the transfer structure on the substrate.

In some embodiments, an orthographic projection of the transfer structure on the substrate at least partially coincides with an orthographic projection of the second data sub-line on the substrate; and an orthographic projection of the dummy transfer structure on the substrate at least partially coincides with an orthographic projection of the second data line on the substrate.

In some embodiments, the transfer structure includes a first transfer portion coupled to the second data sub-line, and a second transfer portion coupled to the first transfer portion and the transfer signal line; the dummy transfer structure includes a third transfer portion coupled to the second data line, and a fourth transfer portion coupled to the third transfer portion and separated from the transfer signal line; and the transfer signal line, the second transfer portion, and the fourth transfer portion are arranged in the same layer.

In some embodiments, an average size of a part of a data line in the second sub-pixel region in the first direction is greater than an average size of a part of a data line in the first sub-pixel region in the first direction.

In some embodiments, the part of the data line in the second sub-pixel region includes a body portion extending in the second direction, and an extension portion extending from the body portion in the first direction; and an orthographic projection of the extension portion on the substrate at least partially coincides with an orthographic projection of the control signal line on the substrate.

In some embodiments, a size of the extension portion in the second direction is greater than a size of the control signal line in the second direction.

In some embodiments, a distance between the transfer structure and the control signal line in the second direction is greater than or equal to 5 μm.

In some embodiments, the display substrate further includes a plurality of initial lines. A distance between at least one initial line and the transfer structure is less than or equal to 2 μm.

In some embodiments, an orthographic projection of the at least one initial line on the substrate at least partially overlaps with an orthographic projection of the transfer structure on the substrate.

In some embodiments, in the second direction, the transfer structure is located between the transfer signal line and the control signal line.

In some embodiments, a plurality of transfer structures are located on a side of the light-transmissive display region in the second direction, and the plurality of transfer structures are arranged in a shape of at least one “V”.

In some embodiments, the control signal lines include at least one of reset lines or gate lines.

In some embodiments, the display substrate further includes a plurality of transparent signal lines. The transparent signal lines extend in the first direction. An end of each transparent signal line is coupled to a first pixel circuit, and another end of each transparent signal line is coupled to a first light-emitting device in the light-transmissive display region.

In some embodiments, the display substrate further includes a multiplexer located in the peripheral region. The multiplexer is coupled to at least two data lines among the plurality of data lines, and the multiplexer is configured to transmit a same data signal to different data lines of the at least two data lines in a time division manner.

In another aspect, a display device is provided. The display device includes a display substrate and an optical sensor. The display substrate is the display substrate as described in any of the above embodiments. The optical sensor is located on a back side of the display substrate, and the back side of the display substrate is a side opposite to a display side of the display substrate. A light-collecting region of the optical sensor at least partially coincides with the light-transmissive display region of the display substrate.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display device, in accordance with some embodiments;

FIG. 2 is a structural diagram of a display substrate, in accordance with some embodiments;

FIG. 3 is a partial enlarged view of a display substrate, in accordance with some embodiments;

FIG. 4 is a diagram showing positions of sub-pixel regions and light-emitting devices in a main display region of a display substrate, in accordance with some embodiments;

FIG. 5A is an equivalent circuit diagram of a first pixel circuit in a display substrate, in accordance with some embodiments;

FIG. 5B is an equivalent circuit diagram of a second pixel circuit in a display substrate, in accordance with some embodiments;

FIGS. 6A to 6C are diagrams showing structures of a first data line in a display substrate under three perspectives, in accordance with some embodiments;

FIG. 7 is a structural diagram of an active layer in a display substrate, in accordance with some embodiments;

FIG. 8 is a structural diagram of a first conductive layer in a display substrate, in accordance with some embodiments;

FIG. 9 is a structural diagram of a second conductive layer in a display substrate, in accordance with some embodiments;

FIG. 10A is a structural diagram of a third conductive layer in a display substrate, in accordance with some embodiments;

FIG. 10B is a structural diagram of a third conductive layer in a display substrate, in accordance with some other embodiments;

FIG. 11A is a structural diagram of a fourth conductive layer in a display substrate, in accordance with some embodiments;

FIG. 11B is a structural diagram of a fourth conductive layer in a display substrate, in accordance with some other embodiments;

FIG. 12A is a diagram showing a structure of an active layer, a first conductive layer, a second conductive layer and a third conductive layer that are stacked in a display substrate, in accordance with some embodiments;

FIG. 12B is a diagram showing a structure of an active layer, a first conductive layer, a second conductive layer and a third conductive layer that are stacked in a display substrate, in accordance with some other embodiments;

FIG. 12C is a diagram showing a structure of a first conductive layer and a third conductive layer that are stacked in a display substrate, in accordance with some embodiments;

FIG. 12D is a diagram showing a structure of an active layer, a first conductive layer, a second conductive layer, a third conductive layer and a fourth conductive layer that are stacked in a display substrate, in accordance with some other embodiments;

FIG. 13 is a structural diagram of a display substrate, in accordance with some embodiments;

FIG. 14 is a timing diagram of a multiplexer and a plurality of signals in a display substrate, in accordance with some embodiments;

FIG. 15 is a timing diagram showing jumps of data voltages in parasitic capacitors in a display substrate, in accordance with some embodiments;

FIG. 16 shows a display image of a display substrate, in accordance with some embodiments;

FIG. 17 is a diagram showing positions of a plurality of transfer structures in a display substrate, in accordance with some embodiments;

FIG. 18 is a diagram showing positions of a plurality of transfer structures in a display substrate, in accordance with some other embodiments;

FIG. 19 is a flowchart of a method for driving a display substrate, in accordance with some embodiments; and

FIG. 20 is a graph showing remapping of grayscale value and brightness in a method for driving a display substrate, in accordance with some embodiments.

### DETAILED DESCRIPTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” and “second” may explicitly or implicitly include one or more of the features. In the description of the embodiments of the present disclosure, the term “a plurality of” or “the plurality of” means two or more unless otherwise specified.

In the description of some embodiments, the terms such as “coupled” and “connected” and derivatives thereof may be used. For example, the term “connected” may be used in the description of some embodiments to indicate that two or more components are in direct physical or electrical contact with each other. As another example, the term “connected” may be used in the description of some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

As used herein, depending on the context, the term “if” is optionally construed as “when”, “in a case where”, “in response to determining” or “in response to detecting”. Similarly, the phrase “if it is determined” or “if [a stated condition or event] is detected” is, optionally, construed to mean “in a case where it is determined” or “in response to determining” or “in a case where [the stated condition or event] is detected” or “in response to detecting [the stated condition or event]”, depending on the context.

The use of “applicable to” or “configured to” herein means an open and inclusive expression, which does not exclude devices that are applicable to or configured to perform additional tasks or steps.

Additionally, the use of the phrase “based on” is meant to be open and inclusive, since a process, step, calculation or other action that is “based on” one or more of the stated conditions or values may, in practice, be based on additional conditions or value beyond those stated.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

Some embodiments of the present disclosure provide a display device. The display device is a product having a function of displaying an image (including a still image or a moving image, where the moving image may be a video). For example, the display device may be any of a display, a television, a billboard, a digital photo frame, a laser printer with a display function, a telephone, a mobile phone, a painting screen, a personal digital assistant (PDA), a digital camera, a camcorder, a viewfinder, a navigator, a vehicle, a large-area wall, an information search device (e.g., a business search device in a department such as an electronic government, a bank, a hospital or an electric power department), a monitor, and the like. As another example, the display device may be any of a microdisplay, a virtual reality (VR) device including a microdisplay, and an augmented reality (AR) device including a microdisplay.

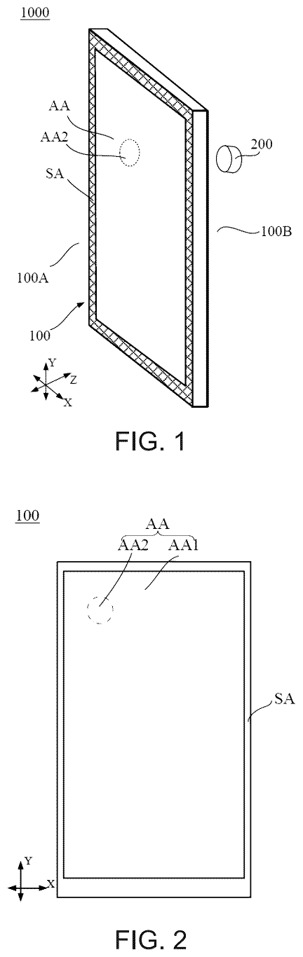

FIG. 1 is a perspective view of a display device. FIG. 2 is a front view of a display device.

Referring to FIGS. 1 and 2, the display device 1000 may include a display substrate 100 and an optical sensor 200. The display substrate 100 is a flat panel capable of displaying an image. For example, the display substrate 100 may be referred to as a screen, and may be a liquid crystal display substrate 100, an organic light-emitting display substrate 100, or the like. For example, the sensor 200 may be an infrared sensor, an ultrasonic sensor, a light detection and ranging (LIDAR) sensor, a radar sensor, a camera sensor, and the like.

Referring to FIG. 1, the display substrate 100 has a display side 100A and a non-display side 100B (i.e., a back side of the display substrate 100). The display side 100A is a side of the display substrate 100 that is capable of displaying images. When a human eye is at the display side 100A, the human eye can view the images displayed on the display substrate 100. The non-display side 100B is opposite to the display side 100A. The optical sensor 200 is disposed on the non-display side 100B of the display substrate 100. Thus, the optical sensor 200 may be referred to as an under-screen sensor. Since the optical sensor 200 needs to receive light signals transmitted through the display substrate 100 from the outside, the display substrate 100 needs to have a high light transmittance in a region corresponding to the optical sensor 200. In view of this, the display substrate 100 may have a display region AA and a peripheral region SA. A direction X in FIG. 1 is an extending direction of a border of the display region AA, e.g., an extending direction of a short border, or is a horizontal direction of the display region AA. A direction Y is an extending direction of another border of the display region AA, e.g., an extending direction of a long border, or is a longitudinal direction of the display region AA. A direction Z is a direction perpendicular to a plane where the display substrate 100 is located. The directions X, Y and Z in the following drawings are defined in the same manner.

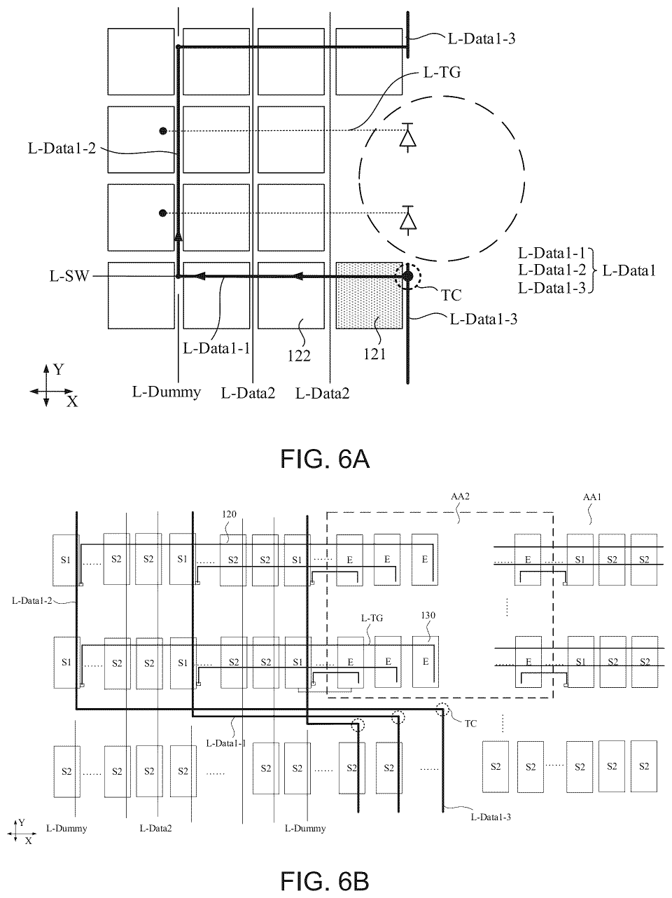

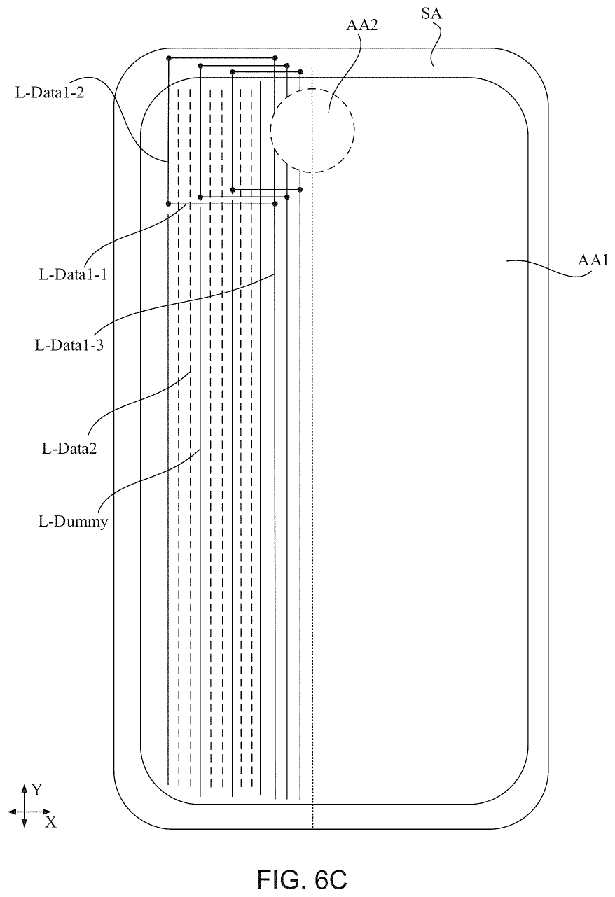

Referring to FIGS. 2 and 6C, the peripheral region SA is located on at least one side (e.g., one side; or four sides, including upper and lower sides and left and right sides) of the display region AA. The display region AA may include a main display region AA1 and a light-transmissive display region AA2 corresponding to the sensor 200, and the main display region AA1 and the light-transmissive display region AA2 do not overlap with each other. The light transmittance of the light-transmissive display region AA2 may be higher than the light transmittance of the main display region AA1.

An orthogonal projection of a light-collecting region of the optical sensor 200 on the display substrate 100 at least partially overlaps with the light-transmissive display region AA2, so that a large amount of light can pass through the display substrate 100 to be received by the optical sensor 200. For example, a part of the orthogonal projection of the light-collecting region of the optical sensor 200 on the display substrate 100 is located within the light-transmissive display region AA2. As another example, all of the orthogonal projection of the light-collecting region of the optical sensor 200 on the display substrate 100 is located within the light-transmissive display region AA2. The main display region AA1 is a region in the display region AA other than the light-transmissive display region AA2.

Some embodiments of the present disclosure provide a display substrate 100. The display substrate 100 may be included in the display device 1000.

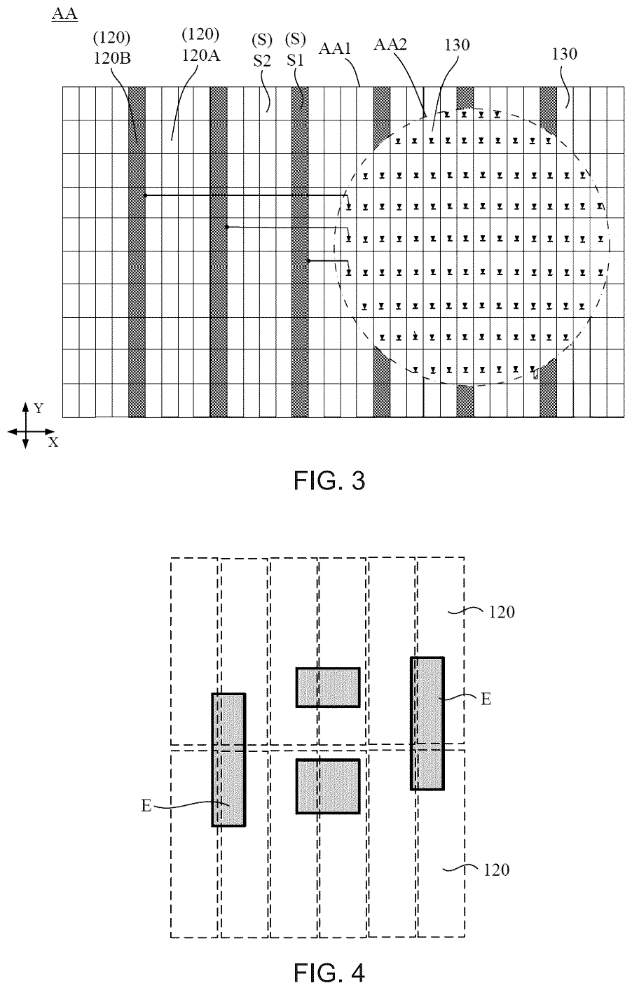

As shown in FIGS. 3 and 6B, the display region AA includes a plurality of display unit regions that are arranged in an array. Each display unit region includes a plurality of display sub-regions 130. Each display sub-region 130 includes a light-emitting device E. It should be noted that the light-emitting devices in the main display region AA1 are hidden in FIGS. 3 and 6B.

As an example, the plurality of display sub-regions 130 include a first display sub-region 130 configured to emit light of a first color, a second display sub-region 130 configured to emit light of a second color, and a third display sub-region 130 configured to emit light of a third color. The first color, the second color, and the third color may be three primary colors. For example, the first color is red, the second color is green, and the third color is blue. Accordingly, the plurality of display sub-regions 130 include a red display sub-region 130, a green display sub-region 130, and a blue display sub-region 130. As another example, the plurality of display sub-regions 130 may further include a fourth display sub-region 130 for emitting white light. The plurality of display sub-regions 130 in the display unit region can cooperate to emit white light.

In some examples, the display unit region includes four display sub-regions, which are arranged as the following rule: one display sub-region 130 of the first color, one display sub-region 130 of the second color, one display sub-region 130 of the third color, and one display sub-region 130 of the second color.

For example, the display sub-region 130 of the first color is the red display sub-region, the display sub-regions 130 of the second color are the green display sub-regions, and the display sub-region 130 of the third color is the blue display sub-region 130. The red display sub-region 130 includes a red light-emitting device E, the green display sub-region 130 includes a green light-emitting device E, and the blue display sub-region 130 includes a blue light-emitting device E. That is, in this example, the display unit region includes one red light-emitting device E, one blue light-emitting device E and two green light-emitting devices E.

For example, the light-emitting device E may be any of a light-emitting diode (LED), an organic light-emitting diode (OLED), a quantum dot light-emitting diode (QLED), and a tiny LED (including a mini LED or a micro LED). The light-emitting device E (e.g., OLED or QLED) includes a cathode and an anode. The light-emitting device E is lit when a current is created between the anode and the cathode.

As shown in FIGS. 3 and 6B, in order to improve the light transmittance of the light-transmissive display region AA2 of the display substrate, no pixel circuit is provided in the light-transmissive display region AA2. The light-emitting device in the light-transmissive display region AA2 receives the electrical signal provided by the pixel circuit in the main display region AA1 to emit light.

The main display region AA1 includes a plurality of pixel unit regions arranged in an array. Each pixel unit region includes a plurality of sub-pixel regions 120. The plurality of sub-pixel regions 120 may include normal sub-pixel regions 120A and dummy sub-pixel regions 120B. Each sub-pixel region 120 includes a pixel circuit S. For example, the dummy sub-pixel region 120B includes a first pixel circuit S1, and the first pixel circuit S1 is coupled to a first light-emitting device through a conductive line; the normal sub-pixel region 120A includes a second pixel circuit S2, and the second pixel circuit S2 is coupled to a second light-emitting device.

In some embodiments, a plurality of second pixel circuits S2 are spaced apart and distributed between the first pixel circuits S1.

For example, in a first direction X, at least one dummy sub-pixel region 120B is located between two normal sub-pixel regions 120A. It can be understood that, in the first direction X, one first pixel circuit S1 is located between two second pixel circuits S2.

In some examples, the number of sub-pixel regions 120 in the pixel unit region may be equal to the number of display sub-regions 130 in the display unit region, and a plurality of pixel circuits S in a single pixel unit region may be coupled to a plurality of light-emitting devices E in a single display unit region.

In some embodiments, in the main display region AA1, the pixel circuit S in the sub-pixel region 120 and the light-emitting device in the display sub-region 130 may partially overlap or completely overlap. For example, as shown in FIG. 4, in the main display region AA1, a portion of a light-emitting device in a display sub-region 130 may at least partially overlap a pixel circuit, and another portion of the light-emitting device may at least partially overlap another pixel circuit.

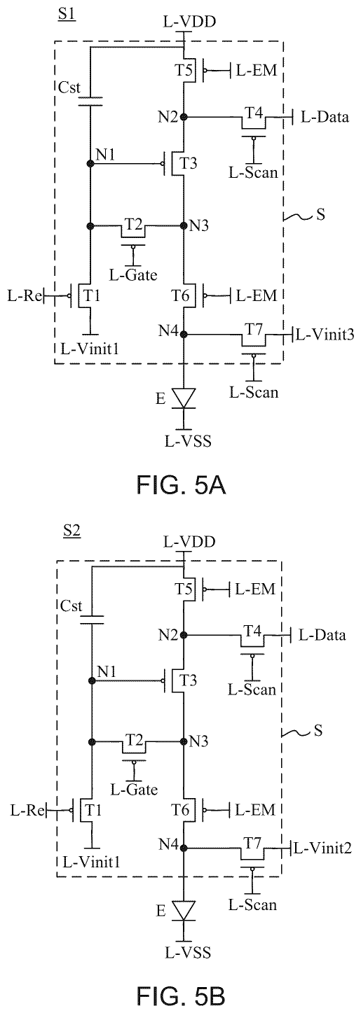

The display substrate 100 may further include a plurality of signal lines. For example, as shown in FIGS. 5A and 5B, the plurality of signal lines may include data lines L-Data configured to transmit data signals, gate lines L-Gate configured to transmit gate signals, scan lines L-Scan configured to transmit scan signals, reset lines L-Re configured to transmit reset signals, enable lines L-EM configured to transmit enable signals, first initial lines L-Vinit1 configured to transmit first initial signals, second initial lines L-Vinit2 configured to transmit second initial signals, third initial lines L-Vinit3 configured to transmit third initial signals, first power lines L-VDD configured to transmit first power supply voltages VDD (e.g., high voltages), and second power lines L-VSS configured to transmit second power supply voltages VSS (e.g., low voltages).

The gate lines L-Gate, the scan lines L-Scan, the reset lines L-Re, the enable lines L-EM, the first initial lines L-Vinit1, the second initial lines L-Vinit2 and the third initial lines L-Vinit3 may extend in a row direction (first direction X) of the display substrate. The first power lines L-VDD may extend in a column direction (second direction Y) of the display substrate.

A plurality of data lines L-Data include a plurality of first data lines L-Data1 and a plurality of second data lines L-Data2. The first data line L-Data1 is coupled to first pixel circuits S1, and the second data line L-Data2 is coupled to second pixel circuits S2.

As shown in FIGS. 6A to 6C, the first data line L-Data1 may include a transfer signal line L-Data1-1 extending in the first direction, and a first data sub-line L-Data1-2 and a second data sub-line L-Data1-3 extending in the second direction. The second data lines L-Data2 extend in the second direction. In FIGS. 6A and 6B, the first data lines L-Data1 are represented by thick black lines, and the second data lines L-Data2 are represented by thin black lines. In FIG. 6C, the first data lines L-Data1 are represented by solid black lines, and the second data lines L-Data2 are represented by dotted black lines.

The structure of the pixel circuit S varies, which may be set according to actual needs. For example, the pixel circuit S may include at least two transistors (denoted by T) and at least one capacitor (denoted by C). For example, the pixel circuit S may be of a “2T1C” structure, a “6T1C” structure, a “7T1C” structure, a “6T2C” structure, or a “7T2C” structure.

For example, as shown in FIG. 5A, the first pixel circuit S1 of the “7T1C” structure includes, a first transistor T1, a second transistor T2, a third transistor T3, a fourth transistor T4, a fifth transistor T5, a sixth transistor T6, a seventh transistor T7, a capacitor Cst; and the first pixel circuit S1 is coupled to a light-emitting device E.

A control electrode of the first transistor T1 is coupled to the reset line L-Re, a first electrode of the first transistor T1 is coupled to the first initial line L-Vinit1, and a second electrode of the first transistor T1 is coupled to a first node N1.

A control electrode of the second transistor T2 is coupled to the gate line L-Gate, a first electrode of the second transistor T2 is coupled to a third node N3, and a second electrode of the second transistor T2 is coupled to the first node N1.

A control electrode of the third transistor T3 is coupled to the first node N1, a first electrode of the third transistor T3 is coupled to a second node N2, and a second electrode of the third transistor T3 is coupled to the third node N3.

A control electrode of the fourth transistor T4 is coupled to the scan line L-Scan, a first electrode of the fourth transistor T4 is coupled to the data line L-Data, and a second electrode of the fourth transistor T4 is coupled to the second node N2.

A control electrode of the fifth transistor T5 is coupled to the enable line L-EM, a first electrode of the fifth transistor T5 is coupled to the first power line L-VDD, and a second electrode of the fifth transistor T5 is coupled to the second node N2.

A control electrode of the sixth transistor T6 is coupled to the enable line L-EM, and a first electrode of the sixth transistor T6 is coupled to the third node N3, and a second electrode of the sixth transistor T6 is coupled to a fourth node N4.

A control electrode of the seventh transistor T7 is coupled to the scan line L-Scan, a first electrode of the seventh transistor T7 is coupled to the third initial line L-Vinit3, and a second electrode of the seventh transistor T7 is coupled to the fourth node N4.

A first electrode plate of the capacitor Cst is coupled to the first power line L-VDD, and a second electrode plate of the capacitor Cst is coupled to the first node N1.

An anode of the first light-emitting device E is coupled to the fourth node N4, and a cathode of the first light-emitting device E is coupled to the second power line L-VSS.

In some embodiments, the fourth transistor T4 is configured to be turned on (i.e., create a path between the second node N2 and the data line L-Data) in response to the scan signal being at an active level, transmit the data signal to the first node N1, and charge the capacitor Cst. The third transistor T3 is configured to control a magnitude of a current flowing through the third transistor T3 in response to a level of the first node N1. Since the light-emitting device E and a driving transistor (i.e., the third transistor T3) are connected in series, the luminance of the light-emitting device E varies with the magnitude of the current.

In some examples, a reset line L-Re of an n-th row of pixel circuits S may be replaced by a scan line L-Scan coupled to the n−1-th row of pixel circuits, which is not limited here.

In some embodiments, as shown in FIG. 5B, the second pixel circuit S2 has the same structure as the first pixel circuit S1, that is, the second pixel circuit S2 also be of the above-mentioned 7T1C structure. The difference between the second pixel circuit S2 and the first pixel circuit S1 may include that: the first electrode of the seventh transistor T7 in the second pixel circuit S2 is coupled to the second initial line L-Vinit2, and the fourth node N4 is coupled to the anode of the second light-emitting device E. In some other embodiments, the first electrodes of the seventh transistors T7

in the second pixel circuit S2 and the first pixel circuit S1 may be coupled to the same initial line, which is not limited here.

As shown in FIGS. 6A to 6C, the display substrate further includes a plurality of dummy lines L-Dummy. The dummy lines L-Dummy extend in the second direction Y, and the plurality of dummy lines L-Dummy are arranged in parallel and at intervals in the first direction X.

There may be a fixed number of second data lines L-Data2 between two adjacent dummy lines L-Dummy in the first direction X. For example, there are seven second data lines L-Data2 or five second data lines L-Data2 between two adjacent dummy lines L-Dummy in the first direction X, which is not limited here.

A single first data sub-line L-Data1-2 as mentioned above may be a part of a single dummy line L-Dummy. A part of the dummy line L-Dummy that is used as the first data sub-line L-Data1-2 is disconnected from another part of the dummy line L-Dummy.

The first data line L-Data1 uses the dummy line L-Dummy and the transfer signal line L-Data1-1 to transmit the data signal avoiding the light-transmissive display region AA2. For example, as shown in FIG. 6C, for the plurality of first data lines L-Data1 arranged continuously in the first direction X, dummy lines L-Dummy arranged continuously in the first direction X are respectively used as first data sub-lines L-Data1-2 of the first data lines L-Data1.

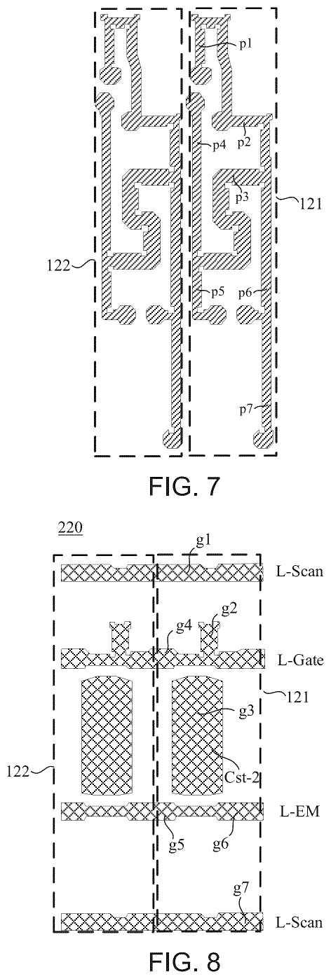

As shown in FIG. 6A, the plurality of sub-pixel regions 120 of the display substrate 100 further include a first sub-pixel region 121 and a second sub-pixel region 122. As shown in FIGS. 7 to 11B, in some embodiments, the display substrate includes a semiconductor layer 210, a first conductive layer 220, a second conductive layer 230, a third conductive layer 240, and a fourth conductive layer 250 that are disposed in a direction away from a substrate.

As shown in FIG. 7, a material of the semiconductor layer 210 may include a low temperature poly-silicon (LTPS) material, or may include a low temperature polycrystalline oxide (LTPO) material, or may include other suitable materials, which is not limited herein.

Materials of the first conductive layer 220, the second conductive layer 230, the third conductive layer 240, the fourth conductive layer 250 may each include a metal material, an alloy material, or other conductive material. The metal material is, for example, aluminum (Al), copper (Cu), silver (Ag), magnesium (Mg), ytterbium (Yb), lithium (Li), etc.

As shown in FIG. 7, the semiconductor layer 210 may include active layers of a plurality of transistors in the pixel circuit. Considering an example where the pixel circuit in FIG. 5A includes the first transistor T1 to the seventh transistor T7, the semiconductor layer 210 may include active layers (p1 to p7) of the first transistor T1 to the seventh transistor T7.

In some examples, the active layers p1 to p7 of the first transistor T1 to the seventh transistor T7 are connected to each other to be of a one-piece structure.

In some embodiments, a first insulating layer may further be provided between the semiconductor layer 210 and the first conductive layer 220. A material of the first insulating layer may be any or a combination of oxides, nitrides or oxynitrides, such as silicon oxide, silicon nitride, or silicon oxynitride, which is not limited herein.

As shown in FIG. 8, in some embodiments, the first conductive layer 220 may include the gate lines L-Gate, the scan lines L-Scan, the enable lines L-EM (also called light-emitting control signal lines), control electrodes g1 to g7 of the first transistor T1 to the seventh transistor T7, and the second electrode plate Cst-2 of the capacitor Cst.

In some examples, the control electrode g2 of the second transistor, the control electrode g4 of the fourth transistor, and the gate line L-Gate are connected to each other to be of a one-piece structure.

In some examples, the control electrode g1 of the first transistor is located on a side of the gate line L-Gate away from the control electrode g3 of the third transistor.

In some examples, the control electrode g5 of the fifth transistor, the control electrode g6 of the sixth transistor T6, the enable line L-EM are connected to each other to be of a one-piece structure.

In some examples, the control electrode g7 of the seventh transistor and the scan line L-Scan are connected to each other to be of a one-piece structure.

In some embodiments, a second insulating layer may further be provided between the first conductive layer 220 and the second conductive layer 230. A material of the second insulating layer may be any or a combination of oxides, nitrides or oxynitrides, such as silicon oxide, silicon nitride, or silicon oxynitride, which is not limited herein.

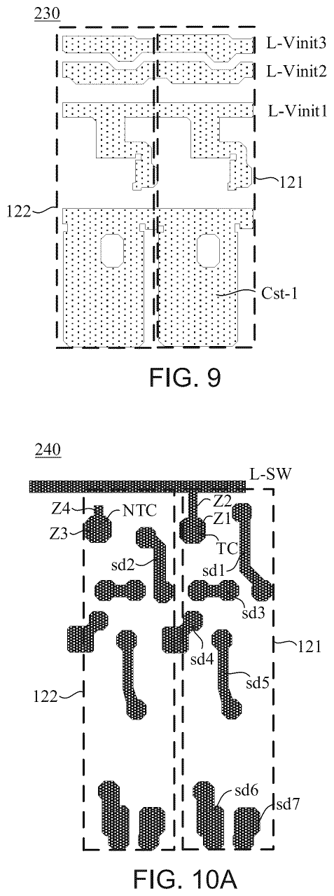

As shown in FIG. 9, in some embodiments, the second conductive layer 230 may include the first initial lines L-Vinit1, the second initial lines L-Vinit2, the third initial lines L-Vinit3, and the first electrode plate Cst-1 of the capacitor Cst.

In some examples, the first initial line L-Vinit1, the second initial line L-Vinit2, and the third initial line L-Vinit3 are sequentially arranged in a direction away from the first electrode plate Cst-1 of the capacitor Cst.

In some examples, the first initial line L-Vinit1 includes a first body portion extending in the first direction and a first extension portion extending in a direction proximate to the first electrode plate Cst-1 of the capacitor Cst.

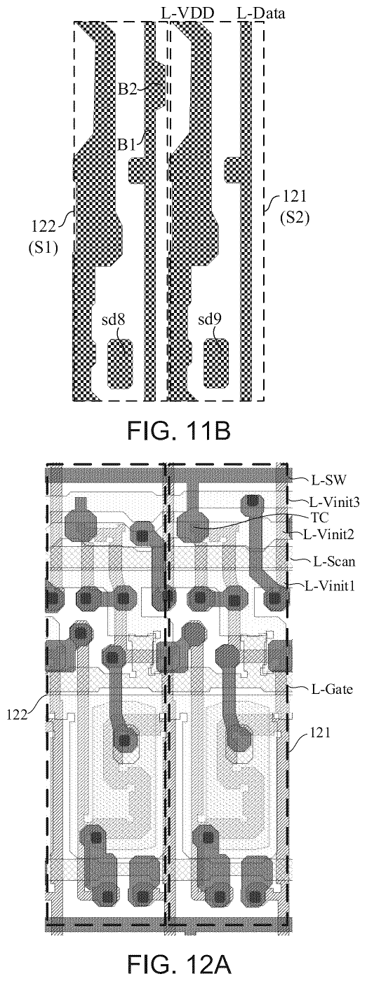

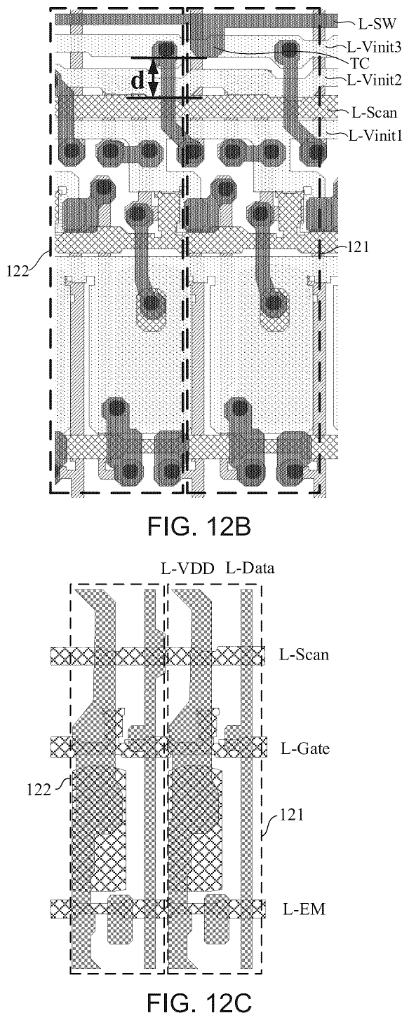

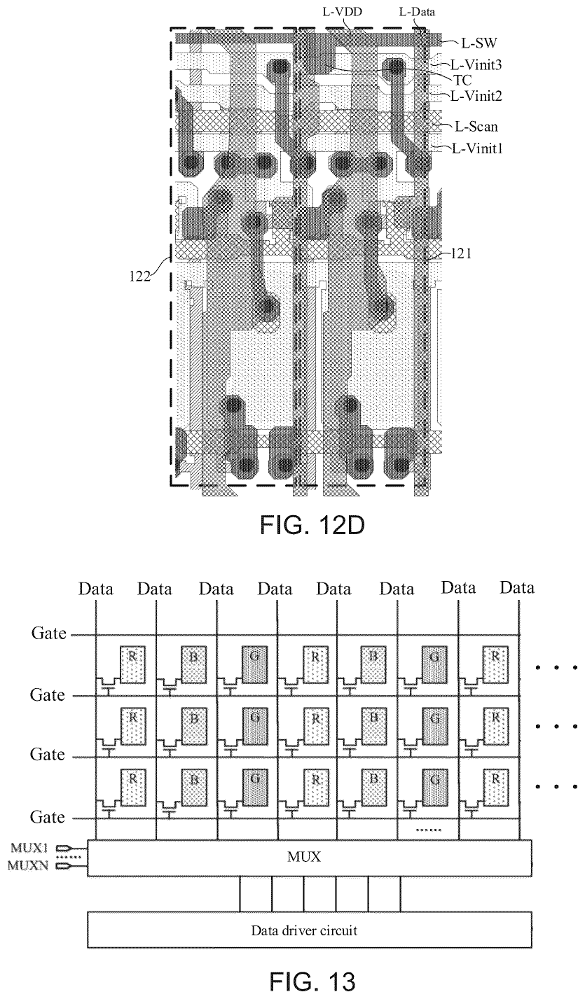

In some examples, as shown in FIGS. 12A, 12B, and 12D, in the second direction, a single scan line L-Scan is located between a single first initial line L-Vinit1 and a single second initial line L-Vinit2.

In some embodiments, a third insulating layer may further be provided between the second conductive layer 230 and the third conductive layer 240. A material of the third insulating layer may be any or a combination of oxides, nitrides or oxynitrides, such as silicon oxide, silicon nitride, or silicon oxynitride, which is not limited herein.

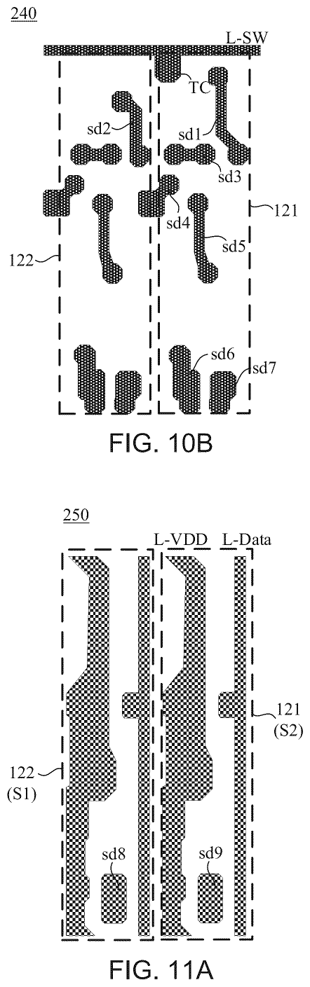

As shown in FIG. 10A, in some embodiments, the third conductive layer 240 may include a transition line L-SW and a plurality of transition members.

The transition line L-SW extends in the first direction and is located between a plurality of pixel circuits.

In some examples, the plurality of transition members include a first transition member sd1 to a seventh transition member sd7.

The first transition member sd1 may couple the third initial line L-Vinit3 to the first electrode of the seventh transistor T7 in the second pixel circuit S2.

The second transition member sd2 may couple the second initial line L-Vinit2 to the first electrode of the seventh transistor T7 in the first pixel circuit S1.

The third transition member sd3 may couple the first electrode of the first transistor T1 to the first initial line L-Vinit1.

The fourth transition member sd4 may couple the first electrode of the fourth transistor T4 to the data line L-Data.

The fifth transition member sd5 may couple the second electrode of the fourth transistor T4 to the first electrode of the third transistor T3.

The sixth transition member sd6 may couple the first electrode of the fifth transistor T5 to the first electrode plate of the capacitor Cst, and the sixth transition member sd6 may be coupled to the first power line L-VDD to obtain the first power supply voltage.

In some embodiments, a fourth insulating layer may further be provided between the third conductive layer 240 and the fourth conductive layer 250. A material of the fourth insulating layer may be any or a combination of oxides, nitrides or oxynitrides, such as silicon oxide, silicon nitride, or silicon oxynitride, which is not limited herein.

As shown in FIG. 11A, in some embodiments, the fourth conductive layer 250 may include the first power lines L-VDD, the data lines L-Data, an eighth transition member sd8, and a ninth transition member sd9.

In some examples, as shown in FIG. 11A, in the first pixel circuit S1, the seventh transition member sd7 in the third conductive layer 240 is coupled to the second electrode of the sixth transistor T6 and the eighth transition member sd8 in the fourth conductive layer 250. The eighth transition member sd8 is coupled to the anode of the first light-emitting device E, so that the second electrode of the sixth transistor T6 is coupled to the anode of the first light-emitting device E.

In some other examples, as shown in FIG. 11A, in the second pixel circuit S2, the seventh transition member sd7 in the third conductive layer 240 is coupled to the second electrode of the sixth transistor T6 and the ninth transition member sd9 in the fourth conductive layer 250. The ninth transition member sd9 is coupled to the anode of the second light-emitting device E, so that the second electrode of the sixth transistor T6 is coupled to the anode of the second light-emitting device E.

In some embodiments, as shown in FIGS. 6A to 6C, the first data signal line L-Data1 is configured to provide a data signal to a plurality of light-emitting devices located in the same column in the display substrate. For example, the first data sub-line L-Data1-2 of the first data signal line L-Data1 is configured to provide the data signal to multiple first light-emitting devices in the column located in the light-transmissive display region; and the second data sub-line L-Data1-3 of the first data signal line L-Data1 is configured to provide the data signal to multiple second light-emitting devices in the column located in the main display region.

For example, a single first data line L-Data1 includes a plurality of first data sub-lines L-Data1-2 extending in the second direction, and the plurality of first data sub-lines L-Data1-2 are arranged in parallel and at intervals in the first direction. The plurality of first data sub-lines L-Data1-2 are respectively coupled to transfer signal lines L-Data1-1 extending in the first direction, and the transfer signal lines L-Data1-1 are also coupled to second data sub-lines L-Data1-3 extending in the second direction. The plurality of first data sub-lines L-Data1-2 are coupled to a plurality of first light-emitting devices in the same column in the light-transmissive display region. In addition, an end of the first data sub-line L-Data1-2 away from the transfer signal line L-Data1-1 may also be coupled to another second data sub-line L-Data1-3 extending in the second direction through a conductive line, thereby forming a complete path for the data signal.

It should be noted that the transfer signal line L-Data1-1 may be a part of the transition line L-SW, which is not limited here. In addition, the above-mentioned conductive line may transmit, through a transition line L-SW, the data signal back to the another second data sub-line L-Data1-3, or the above-mentioned conductive line may be an additional signal line to transmit the data signal back to the another second data sub-line L-Data1-3, which is not limited here.

In this way, the data signal is transmitted to the first pixel circuit by sequentially passing through the second data sub-line L-Data1-3, the transfer signal line L-Data1-1, and the first data sub-line L-Data1-2, and the first pixel circuit drives the first light-emitting device in the light-transmissive display region to emit light.

Different second data sub-lines L-Data1-3 may be coupled to different transfer signal lines L-Data1-1. In addition, different transfer signal lines L-Data1-1 may also be coupled to different first data sub-lines L-Data1-2.

As shown in FIGS. 6A and 6B, the first pixel circuit is coupled to the first light-emitting device in the light-transmissive display region AA2 through a transparent signal line L-TG (indicated by a dotted line in FIG. 6A). The transparent signal line L-TG may be, for example, an indium tin oxide (ITO) line.

In some embodiments, the display substrate 100 further includes a transparent conductive layer. For example, the display substrate 100 includes a first transparent conductive layer, a second transparent conductive layer, and a third transparent conductive layer that are sequentially stacked in a direction away from the substrate. The plurality of transparent conductive layers are located on a side of the plurality of conductive layers away from the substrate.

The first transparent conductive layer includes first light-transmissive signal lines L-TG extending in the first direction. An end of a first light-transmissive signal line L-TG is coupled to a first pixel circuit, and another end of the first light-transmissive signal line L-TG is coupled to a light-emitting device of the first color in the light-transmissive display region AA2.

The second transparent conductive layer includes second light-transmissive signal lines L-TG extending in the first direction. An end of a second light-transmissive signal line L-TG is coupled to a first pixel circuit, and another end of the second light-transmissive signal line L-TG is coupled to a light-emitting device of the second color in the light-transmissive display region AA2.

The third transparent conductive layer includes third light-transmissive signal lines L-TG extending in the first direction. An end of a third light-transmissive signal line L-TG is coupled to a first pixel circuit, and another end of the third light-transmissive signal line L-TG is coupled to a light-emitting device of the third color in the light-transmissive display region AA2.

Since the first light-transmissive signal lines L-TG, the second light-transmissive signal lines L-TG and the third light-transmissive signal lines L-TG have high light transmittance, the light transmittance of the light-transmissive display region AA2 will not be affected.

In some examples, the light-transmissive signal line L-TG is not directly coupled to the first pixel circuit S1. The display substrate 100 may further include connection lines extending in the first direction. An end of the connection line is coupled to the first pixel circuit, and another end of the connection line extends to an edge of the main display region AA1 and is coupled to the light-transmissive signal line. The connection line may be a metal signal line. The electrical conductivity of the connection line is greater than the electrical conductivity of the light-transmissive signal line. Therefore, the resistance can be reduced.

As shown in FIG. 6A, the first sub-pixel region 121 includes an intersection of the second data sub-line L-Data1-3 and the transfer signal line L-Data1-1. The second sub-pixel regions 122 are sub-pixel regions 122 of the plurality of sub-pixel regions 120 other than the first sub-pixel regions 121. The first sub-pixel region 121 is provided therein with a transfer hole that penetrates through the fourth insulating layer and a transfer structure TC that fills the transfer hole to be coupled to the second data sub-line L-Data1-3 and the transfer signal line L-Data1-1. The transfer structure TC increases a first capacitance value of a parasitic capacitor between a data line in the first sub-pixel region 121 and a peripheral control signal line (e.g., a reset line, or a scan line, or a gate line) (since the parasitic capacitor is created with the data line, it is hereinafter referred to as the parasitic capacitor of the data line). Therefore, the first capacitance value of the parasitic capacitor of the data line in the first sub-pixel region 121 is greater than the second capacitance value of the parasitic capacitor of the data line in the second sub-pixel region 122.

For example, the second capacitance value of the parasitic capacitor of the data line in the second sub-pixel region 122 and a capacitance value of the parasitic capacitor of the data line in the pixel region 120 where the transition line L-SW is provided are in a range of 0.19 fF to 0.31 fF; and the first capacitance value of the parasitic capacitor of the data line in the first sub-pixel region 121 is in a range of 0.4 fF to 0.52 fF. For example, the second capacitance value of the parasitic capacitor of the data line in the second sub-pixel region 122 is approximately 0.25 fF; and the first capacitance value of the parasitic capacitor of the data line in the first sub-pixel region 121 is approximately 0.46 fF.

In some examples, as shown in FIGS. 12A and 12B, in the second direction, the transfer structure TC may be located between the transition line L-SW and the control signal line.

In some other examples, in the third direction, the transfer structure TC may be located between the data line and the control signal line. For example, as shown in FIG. 8, the control signal line is located in the first conductive layer 220; as shown in FIG. 11A, the data line is located in the fourth conductive layer 250; and as shown in FIGS. 10A and 10B, the transfer structure TC is located in the third conductive layer 240 between the first conductive layer 220 and the fourth conductive layer 250.

As shown in FIG. 13, the display substrate 100 may further include multiplexer(s) (MUX(s)). The multiplexer(s) are located in the peripheral region of the display substrate. The multiplexer is coupled to at least two data lines among the plurality of data lines. The multiplexer is configured to transmit the same data signal to different data lines of the at least two data lines in a time division manner. The multiplexer may be connected in series between the data lines and a data driver circuit (source integrated circuit (IC)). Therefore, the number of data lines on the display substrate is reduced, which is conducive to realizing the full screen of the display device.

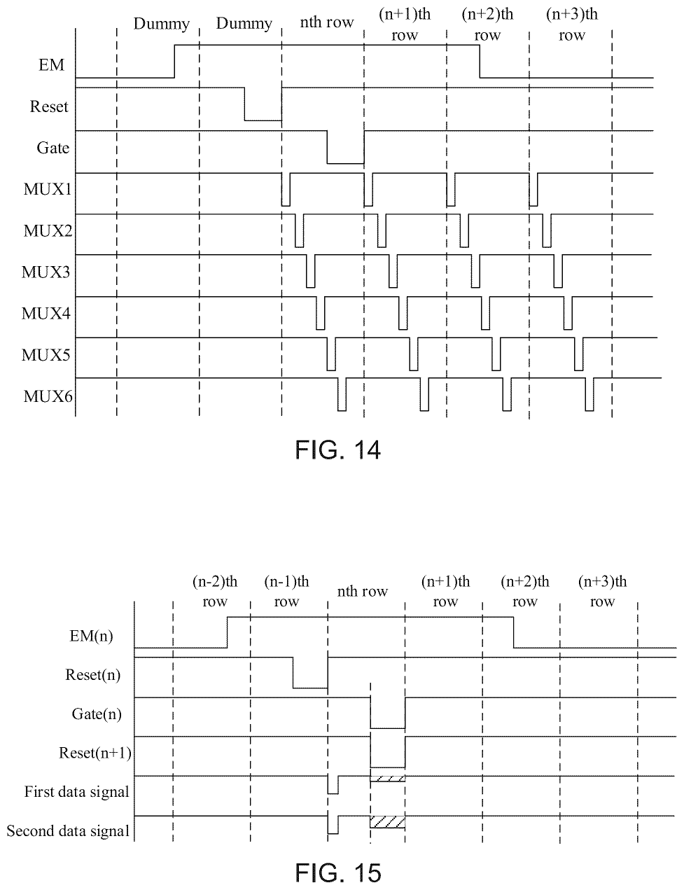

As shown in FIG. 14, a method of driving the MUX is usually as follows. The MUX is turn on and writes the data signal to the parasitic capacitor of the data line in the main display region AA1, and then MUX is turned off; next, the gate line outputs the gate signal so that the data signal is written into the light-emitting device.

When the MUX is turned off, the data signal is stored in the parasitic capacitor of the data line and is in a passive control state, which is easily disturbed by external signal fluctuations. When the gate signal of the gate line and/or the scan signal of the scan line L-Scan jumps, the data signal stored in the parasitic capacitor of the data line will be disturbed by the signal jump.

As shown in FIG. 15, since the larger the parasitic capacitor is, the greater the degree of the data signal jump of the parasitic capacitor caused by the interference from the external signal jump, the deviation of the data voltage of the data signal stored in the parasitic capacitor of the data line in the first sub-pixel region 121 caused by the interference from the of the gate signal and/or scan signal jump is greater than the deviation of the data voltage of the data signal stored in the parasitic capacitor of the data line in the second sub-pixel region 122 caused by the interference from the gate signal and/or scan signal jump. As a result, the brightness of the light-emitting device coupled to the pixel circuit in the first sub-pixel region 121 is greater than the brightness of the light-emitting device coupled to the pixel circuit in the second sub-pixel region 122, leading to the problem of uneven display brightness of the display substrate.

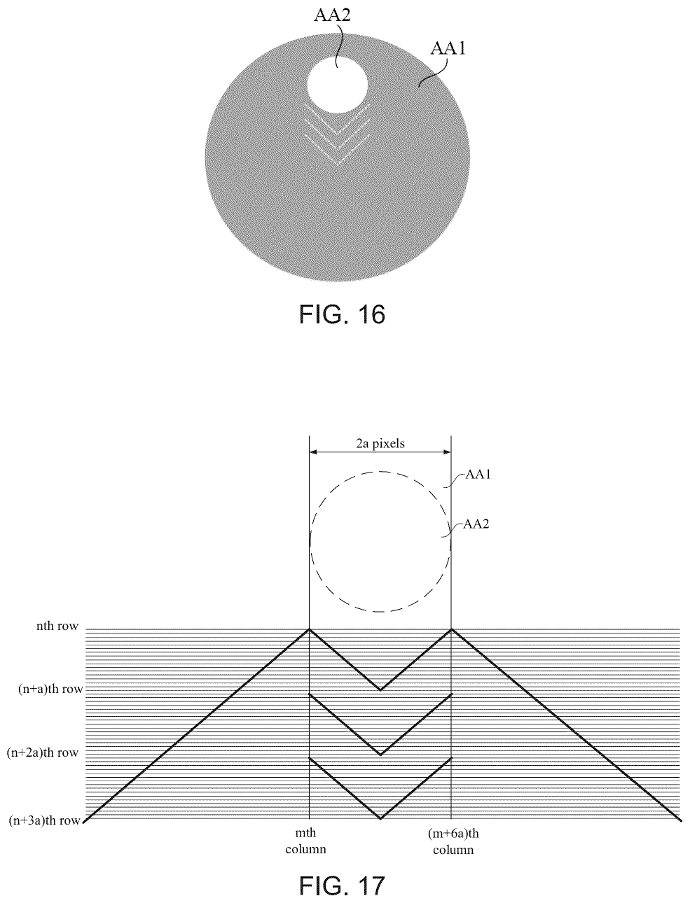

As shown in FIG. 16, the brightness of the light-emitting device coupled to the pixel circuit in the first sub-pixel region 121 is greater than the brightness of the light-emitting device coupled to the pixel circuit in the second sub-pixel region 122. Considering an example in which the first sub-pixel regions 121 are arranged in a shape of “V”, the light-emitting devices coupled to the pixel circuits in the first sub-pixel regions 121 form a “V”-shaped bright band below the light-transmissive display region.

In light of this, the display substrate 100 provided in the embodiments of the present disclosure can overcome the problem of uneven display brightness.

For ease of understanding, the following description is introduced by taking an example in which the control signal line is the scan line L-Scan and the parasitic capacitor of the data line is the parasitic capacitor between the data line and the scan line L-Scan. However, the control signal line and parasitic capacitor should not be limited thereto.

The transfer structure TC is coupled to the first data line L-Data1 and is located between the first data line L-Data1 and the scan line L-Scan in the third direction Z, resulting in an increase in the parasitic capacitor between the part of the data line in the first sub-pixel region 121 and the scan line L-Scan, in turn increasing the first capacitance value of the parasitic capacitor between the first data line L-Data1 and the scan line L-Scan. And/or, an orthographic projection of the transfer structure TC on the substrate is not completely covered by an orthographic projection of the data line on the substrate, resulting in an increase in the parasitic capacitor between the part of the data line in the first sub-pixel region 121 and the scan line L-Scan, and in turn increasing the first capacitance value of the parasitic capacitor between the first data line L-Data1 and the scan line L-Scan.

The display substrate 100 provided in the embodiments of the present disclosure increases the parasitic capacitor between the part of the data line in the second sub-pixel region 122 and the scan line L-Scan, so that the difference between the first capacitance value of the parasitic capacitor of the first data line L-Data1 and the second capacitance value of the parasitic capacitor of the second data line L-Data2 is less than or equal to 0.15 fF. In this way, the difference in data voltage caused by the interference from the peripheral signal jump of the parasitic capacitor in each sub-pixel region 120 may be reduced, which is convenient for unifying the deviation of the data voltage stored in the parasitic capacitor in each sub-pixel region 120, thus facilitating the improvement of the uniformity of the display brightness of the display substrate 100.

Two implementations of increasing the second capacitance value of the parasitic capacitor between the part of the data line in the second sub-pixel region 122 and the scan line L-Scan will be described below. It can be understood that the two implementations are only for the sake of illustration and do not mean that there are only these two implementations.

In the first implementation, as shown in FIG. 10A, the second sub-pixel region 122 further includes a dummy transfer structure NTC. It can be understood that the dummy transfer structure NTC is coupled to a part of the data line in the second sub-pixel region 122 and is separated from the transition line.

It should be noted that the part of the data line in the second sub-pixel region 122 may be a part of the first data line L-Data1 or a part of the second data line L-Data2. In the case where the data line in the second sub-pixel region 122 is a part of the first data line L-Data1, it can be a part of the first data sub-line L-Data1-2, or it can be a part of the second data sub-line L-Data1-3 that is not directly coupled to the transition line (it can also be understood as a part of the second data sub-line L-Data1-3 located outside the first sub-pixel region 121).

In some embodiments, as shown in FIG. 10A, the transfer structure TC includes a first transfer portion Z1 coupled to a part of the data line in the first sub-pixel region 121, and a second transfer portion Z2 coupled to the first transfer portion Z1 and the transition line L-SW. For example, as shown in FIG. 10A, the second transfer portion Z2 may belong to the third conductive layer 240. The first transfer portion Z1 may penetrate through the fourth insulating layer, so that the transition line L-SW in the third conductive layer 240 is coupled to the second data sub-line L-Data1-3 in the fourth conductive layer 250 through the second transfer portion Z2.

As shown in FIG. 10A, the dummy transfer structure NTC includes a third transfer portion Z3 coupled to a part of the data line in the second sub-pixel region 122, and a fourth transfer portion Z4 coupled to the third transfer portion Z3 and separated from the transition line L-SW. For example, as shown in FIG. 10A, the fourth transfer portion Z4 may belong to the third conductive layer 240. The third transfer portion Z3 may penetrate through the fourth insulating layer, so that the fourth transfer portion Z4 in the third conductive layer 240 is coupled to the data line in the fourth conductive layer 250.

It can be understood that, as shown in FIG. 10A, the transition line L-SW, the second transfer portion Z2 and the fourth transfer portion Z4 may be located in the third conductive layer 240. Therefore, the transition line L-SW, the second transfer portion Z2 and the fourth transfer portion Z4 may be formed simultaneously through one patterning process, which improves the manufacturing efficiency of the display substrate.

In some embodiments, the dummy transfer structure NTC and the transfer structure TC may be located between the first conductive layer 220 and the fourth conductive layer 250.

In this way, the dummy transfer structure NTC may shorten the average distance, in the third direction, between the scan signal of the scan line L-Scan in the first conductive layer 220 and the data signal of the data line in the fourth conductive layer 250. Therefore, the parasitic capacitor between the part of the data line in the second sub-pixel region 122 and the scan line L-Scan is increased, which causes the second capacitance value of the parasitic capacitor of the second data line L-Data2 to be increased.

In some embodiments, an area of an orthographic projection of the dummy transfer structure NTC on the substrate is less than or substantially equal to an area of an orthographic projection of the transfer structure TC on the substrate.

The orthographic projection of the dummy transfer structure NTC on the substrate is not completely covered by the orthographic projection of the data line on the substrate. Therefore, the parasitic capacitor between the part of the data line in the second sub-pixel region 122 and the scan line L-Scan is increased, causing the second capacitance value of the parasitic capacitor of the second data line L-Data2 to be increased.

For example, the area of the orthographic projection of the dummy transfer structure NTC on the substrate is less than the area of the orthographic projection of the transfer structure TC on the substrate. In this case, compared with a case where no dummy transfer structure NTC is provided, the dummy transfer structure NTC can increase the capacitance value of the parasitic capacitor between the part of the data line in the second sub-pixel region 122 and the scan line L-Scan, and reduce the difference between the parasitic capacitor in the second sub-pixel region 122 and the parasitic capacitor in the first sub-pixel region 121. In this way, the difference between the first capacitance value of the parasitic capacitor of the first data line L-Data1 and the second capacitance value of the parasitic capacitor of the second data line L-Data2 can be reduced.

For example, the area of the orthographic projection of the dummy transfer structure NTC on the substrate is substantially equal to the area of the orthographic projection of the transfer structure TC on the substrate, so that the parasitic capacitor between the part of the data line in the second sub-pixel region 122 and the scan line L-Scan is substantially equal to the parasitic capacitor between the part of the data line in the first sub-pixel region 121 and the scan line L-Scan. In this way, the capacitance of the part of the data line in each sub-pixel region 120 is substantially equal, so that the first capacitance value of the parasitic capacitor of the first data line L-Data1 and the second capacitance value of the parasitic capacitor of the second data line L-Data2 are substantially equal.

In this way, the difference of each parasitic capacitance due to the interference from the peripheral signal jump may be reduced, which is convenient for unifying the deviation of the data signal stored in each parasitic capacitor, thereby facilitating the improvement of the uniformity of the display brightness of the display substrate.

In some embodiments, the orthographic projection of the transfer structure TC on the substrate may at least partially coincide with the orthographic projection of the part of the second data sub-line L-Data1-3 in the first sub-pixel region 121 on the substrate; and the orthographic projection of the dummy transfer structure NTC on the substrate may at least partially coincide with the orthographic projection of the part of the data line in the second sub-pixel region 122 on the substrate.

In this way, the layout space occupied by the transfer structure TC and the dummy transfer structure NTC in the first direction in the display substrate may be reduced, avoiding affecting the layout space of the pixel circuit in the display substrate, thereby being able to adapt to display substrates using a variety of pixel circuits.

It can be understood that the difference between the dummy transfer structure NTC and the transfer structure TC may only be that the transfer structure TC is coupled to the transfer signal line, and the dummy transfer structure NTC is separated from the transfer signal line.

Therefore, in the first implementation, the dummy transfer structure NTC may increase the parasitic capacitance between the part of the data line in the second sub-pixel region 122 and the scan line L-Scan; furthermore, the second capacitance value of the parasitic capacitor of the second data line L-Data2 may be close to or even substantially equal to the first capacitance value of the parasitic capacitor of the first data line L-Data1. In this way, the difference in data voltage in the parasitic capacitor in each sub-pixel region caused by the interference from the peripheral signal jump may be reduced, which is convenient for unifying the deviation of the data voltage stored in the parasitic capacitor in each sub-pixel region, thereby facilitating the uniformity of the display brightness of the display substrate.

In the second implementation, as shown in FIG. 11B, an average size of the part of the data line in the second sub-pixel region 122 in the first direction is greater than an average size of the part of the data line in the first sub-pixel region 121 in the first direction.

In some embodiments, as shown in FIG. 11B, the part of the data line in the second sub-pixel region 122 includes a body portion (which may be referred to as a second body portion) B1 extending in the second direction, and an extension portion (which may be referred to as a second extension portion) B2 extending from the second body portion B1 in the first direction. A size of the second body portion B1 in the first direction is substantially equal to a size of the part of the data line in the first sub-pixel region 121 in the first direction. Since the part of the data line in the second sub-pixel region 122 has the extension portion B2, the average size of the part of the data line in the second sub-pixel region 122 in the first direction is greater than the average size of the part of the data line in the first sub-pixel region 121 in the first direction.

The orthographic projection of the extension portion B2 in the second sub-pixel region 122 on the substrate at least partially coincides with the orthographic projection of the scan line L-Scan on the substrate. In this way, it may be possible to increase a relative area of two electrode plates of the parasitic capacitor between the part of the data line in the second sub-pixel region 122 and the scan line L-Scan, and in turn increase the parasitic capacitance of the data line in the second sub-pixel region 122.

For example, as shown in FIG. 12C, a relative area M1 of the part of the data line in the second sub-pixel region 122 and the scan line L-Scan is greater than a relative area M2 of the part of the data line in the first sub-pixel region 121 and the scan line L-Scan. Thus, the capacitance value of the parasitic capacitor of the data line in the second sub-pixel region 122 is increased.

In this way, by increasing the capacitance of the parasitic capacitor of the data line in the second sub-pixel region 122, the first capacitance of the parasitic capacitor of the first data line L-Data1 and the second capacitance of the parasitic capacitor of the second data line L-Data2 may be substantially equal.

In some examples, as shown in FIG. 12C, a size of the second extension portion B2 in the second direction is greater than a size of the scan line L-Scan in the second direction.

In this way, the alignment range of the second extension portion B2 and the scan line L-Scan may be increased, the tolerance of alignment errors during the process of manufacturing the display substrate may be improved, and it is ensured that the second extension portion B2 is aligned with the scan line L-Scan. As a result, the second capacitance value of the parasitic capacitor of the data line in the second sub-pixel region 122 is increased.

Therefore, in the second implementation, by increasing the size of the data line in the second sub-pixel region 122 in the first direction, the parasitic capacitance of the data line in the second sub-pixel region 122 and the scan line L-Scan is increased. In this way, by increasing the capacitance of the parasitic capacitor of the data line in the second sub-pixel region 122, the first capacitance of the parasitic capacitor of the first data line L-Data1 and the second capacitance of the parasitic capacitor of the second data line L-Data2 may be substantially equal, which is conducive to unifying the deviation of the data voltage stored in the parasitic capacitor in each sub-pixel region 120, and in turn improving the uniformity of the display brightness of the display substrate.

Secondly, in addition to the above two implementations of increasing the second capacitance value of the parasitic capacitor between the second data line L-Data2 and the scan line L-Scan, the difference between the first capacitance value and the second capacitance value may also be reduced by reducing the first capacitance value of the parasitic capacitor of the data line in the first sub-pixel region 121.

An implementation for reducing the first capacitance value of the parasitic capacitor of the data line in the first sub-pixel region 121 will be described below. It can be understood that this implementation is only for the purpose of illustration and does not mean that there is only one implementation.

In the third implementation, as shown in FIGS. 10B, 12B and 12D, a distance d between the transfer structure TC and the scan line L-Scan in the second direction is greater than or equal to 5 μm.

When the distance d between the transfer structure TC and the scan line L-Scan is 1.45 μm, the first capacitance value of the parasitic capacitor between the part of the data line in the first sub-pixel region 121 and the scan line L-Scan is 0.46 femtofarad (fF).

In this implementation, the transfer structure TC is arranged away from the scan line L-Scan. For example, the transfer hole is arranged close to the transfer signal line, the distance between the transfer structure TC and the scan line L-Scan is increased, and an area of an orthographic projection of the fourth transfer portion on the substrate is reduced.

In this way, the distance d between the transfer structure TC and the scan line L-Scan is greater than or equal to 5 μm, thereby reducing the first capacitance value of the parasitic capacitor in the first sub-pixel region 121.

For example, when the distance d between the transfer structure TC and the scan line L-Scan is 6.7 μm, the first capacitance value of the parasitic capacitor between the part of the data line in the first sub-pixel region 121 and the scan line L-Scan is reduced to 0.32 femtofarad (fF).

Therefore, in the third implementation, by increasing the distance between the transfer structure TC and the scan line L-Scan, the first capacitance value of the parasitic capacitor in the first sub-pixel region 121 may be reduced. In this way, the difference in data voltage in the parasitic capacitor in the first sub-pixel region 121 caused by the interference from the scan signal jump may be reduced, which is convenient for unifying the deviation of the data voltage stored in the parasitic capacitor in each sub-pixel region, thereby facilitating the uniformity of the display brightness of the display substrate.

In addition, in the above three implementations, the difference between the first capacitance value and the second capacitance value is reduced, to reduce the difference between the data voltage jump of the parasitic capacitor in the first sub-pixel region 121 caused by the interference from the scan signal jump and the data voltage jump of the parasitic capacitor in the second sub-pixel region 122 caused by the interference from the scan signal jump. The initial line may also be used to stabilize the jump of the data voltage in the parasitic capacitor in the first sub-pixel region 121.

An implementation of using an initial line to stabilize the jump of the data voltage in the parasitic capacitor in the first sub-pixel region 121 will be described. It should be understood that this implementation is only for the purpose of illustration and does not mean that there is only one implementation.

In the fourth implementation, a distance between at least one initial line and the transfer structure TC is less than or equal to 2 μm.

The initial line is configured to transmit an initial signal with a constant voltage value, and thus the initial line has stable properties. Since the distance between the transfer structure TC and at least one initial line is less than or equal to 2 μm, the initial line may reduce the impact of the data voltage jump of the parasitic capacitor in the first sub-pixel region 121 caused by the interference from the scan signal jump.

Therefore, it may reduce or even eliminate difference in data voltage between the parasitic capacitor in the first sub-pixel region 121 and the parasitic capacitor in the second sub-pixel region 122 caused by the interference from the scan signal jump, and it is convenient for unifying the deviation of the data voltage stored in the parasitic capacitor in each sub-pixel region, and in turn improving the uniformity of the display brightness of the display substrate.

In some embodiments, as shown in FIG. 12A, an orthographic projection of the at least one initial line on the substrate at least partially overlaps with the orthographic projection of the transfer structure TC on the substrate.

For example, as shown in FIG. 12A, the orthographic projection of the transfer structure TC on the substrate at least partially overlaps with orthographic projections of the third initial line L-Vinit3 and the second initial line L-Vinit2 on the substrate.

As another example, as shown in FIG. 12B, the orthographic projection of the transfer structure TC on the substrate at least partially overlaps with an orthographic projection of the third initial line L-Vinit3 on the substrate.

In this way, it may be possible to reduce a distance between the transfer structure TC and the initial line, and in turn improve the effect of the initial line on alleviating the data voltage jump in the parasitic capacitor in the first sub-pixel region 121 disturbed by scan signal jump.

Therefore, in the fourth implementation, by reducing the distance between the transfer structure TC and the initial line, the anti-interference ability of the parasitic capacitor in the first sub-pixel region 121 is improved, which reduces the impact of the data voltage jump in the parasitic capacitor in the first sub-pixel region 121 caused by the interference from the scan signal jump. In this way, it is conducive to unifying the deviation of the data voltage stored in the parasitic capacitor in each sub-pixel region, and in turn improving of the uniformity of the display brightness of the display substrate.

It should be noted that the above four implementations may be implemented individually, or in various combinations, or in combination with other implementations, which is not limited here.

In summary, in the display substrate provided in the embodiments of the present disclosure, the difference between the second capacitance value of the parasitic capacitor, which is between the part of the data line in the second sub-pixel region 122 and the scan line L-Scan, and the first capacitance value of the parasitic capacitor, which is between the part of the data line in the first sub-pixel region 121 and the scan line L-Scan, is less than or equal to 0.15 fF. In this way, the difference in data voltage in the parasitic capacitor in each sub-pixel region caused by the interference of the peripheral signal jump may be reduced, which is convenient for unifying the deviation of the data voltage stored in the parasitic capacitor in each sub-pixel region, thereby facilitating the uniformity of the display brightness of the display substrate.

The embodiments of the present disclosure further provide a method for driving a display substrate. The display substrate is the display substrate as described in any of the above embodiments.

In some embodiments, the display unit region includes one red light-emitting device, one green light-emitting device, and one blue light-emitting device. When the number of columns of first light-emitting devices in the light-transmissive display region is 6a (a being a positive integer) and the columns of first light-emitting devices in the light-transmissive display region are (m+1) th column to (m+6a) th column, the transfer structures are arranged starting from an (n+1) th row.

In some examples, as shown in FIG. 17, the transfer structures arranged from (n+1) th row to (n+a) th row is used to couple with the green light-emitting device in the light-transmitting display area; the transfer structure arranged from the n+a+1 row to the n+2a row is used to couple with the red light-emitting device in the light-transmitting display area; and the transfer structure arranged from the (n+2a+1) th row to the (n+3a) th row is used to couple with the blue light-emitting device in the light-transmitting display area.

The positions of the transfer structures may refer to Table 1. Here, G(x,y) indicates that a green display sub-region is located at an xth row and yth column, and a red display sub-region and a blue display sub-region are similar to the above description, which will not be repeated here.

TABLE 1

| | | | | | | | | |
|---|---|---|---|---|---|---|---|---|
| G pixel | G(n + 1, | G(n + 2, | [symbol] | G(n + a, | G(n + a, | [symbol] | G(n + 2, | G(n + 1, |
| | m + 2) | m + 5) | | m + 3a − 1) | m + 3a + 2) | | m + 5a − 4) | m + 6a − 1) |
| R pixel | R(n + a + 1, | R(n + a + 2, | [symbol] | R(n + 2a, | R(n + 2a, | [symbol] | R(n + a + 2, | R(n + a + 1, |
| | m + 1) | m + 4) | | m + 3a − 2) | m + 3a + 1) | | m + 5a − 5) | m + 6a − 2) |
| B pixel | B(n + 2a + 1, | B(n + 2a + 2, | [symbol] | B(n + 3a, | B(n [symbol] 3a, | [symbol] | B(n + 2a + 2, | B(n + 2a + 1, |
| | m + 3) | m + 6) | | m + 3a) | m + 3a + 3) | | m + 6a − 3) | m + 6a) |

[symbol]

indicates data missing or illegible when filed

Here, a plurality of transfer structures arranged in the (n+1) th row to the (n+a) th row are arranged in a shape of “V”; similarly, a plurality of transfer structures arranged in the (n+a+1) th row to the (n+2a) th row are arranged in a shape of “V”; similarly, a plurality of transfer structures arranged in the (n+2a+1) th row to the (n+3a) th row are arranged in a shape of “V”.

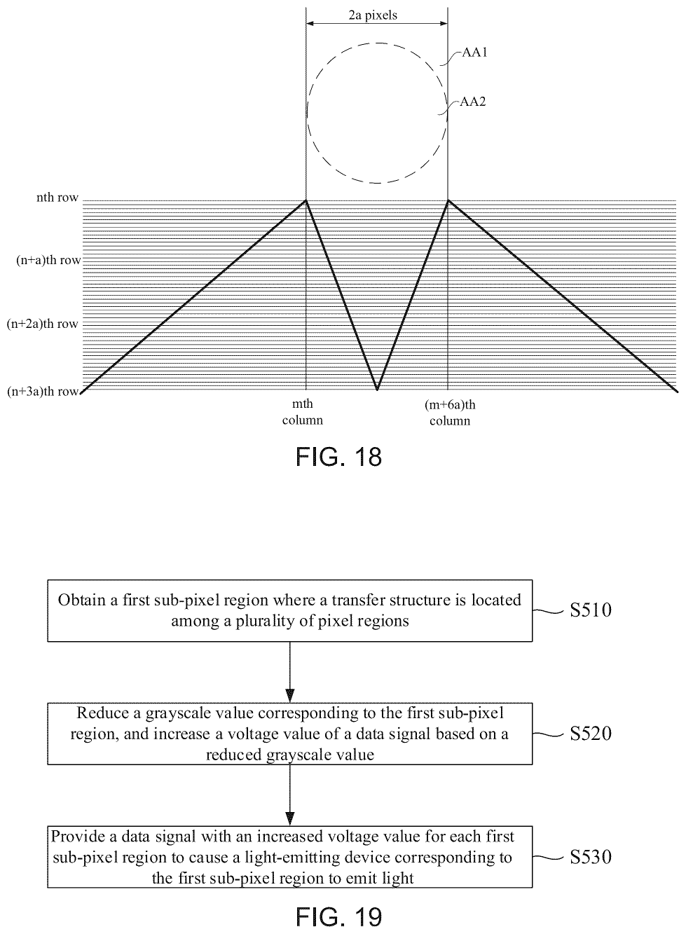

In some other examples, as shown in FIG. 18, the (n+1) th row to the (n+3a) th row are arranged in sequence including a switching structure for coupling with a red light-emitting device in the light-transmitting display area, a switching structure for coupling with a green light-emitting device in the light-transmitting display area, and a switching structure for coupling with a blue light-emitting device in the light-transmitting display area.

The positions of the transfer structures may refer to Table 2. Here, G (x, y) indicates that a green display sub-region is located at an xth row and yth column, and the same is true for a red display sub-region and a blue display sub-region, which will not be repeated here.

TABLE 2

| | | | | | | | | |
|---|---|---|---|---|---|---|---|---|
| G pixel | G(n + 2, | G(n + 5, | [symbol] | G(n + 3a − 1, | G(n + 3a − 1, | [symbol] | G(n + 5m + | G(n + 2, |
| | m + 2) | m + 5) | | m + 3a − 1) | m + 3a + 2) | | 6a − 4) | m + 6a − 1) |
| R pixel | R(n + 1, | R(n + 4, | [symbol] | R(n + 3a − 2, | R(n + 3a − 2, | [symbol] | R(n + 6, | R(n + 3, |
| | m + 1) | m + 4) | | m + 3a − 2) | m + 3a + 1) | | m + 6a − 5) | m + 6a − 2) |
| B pixel | B(n + 3, | B(n + 6, | [symbol] | B(n + 3a, | B(n + 3a, | [symbol] | B(n + 4, | B(n + 1, |
| | m + 3) | m + 6) | | m + 3a) | m + 3a + 3) | | m + 6a − 3) | m + 6a) |

[symbol]

indicates data missing or illegible when filed

Here, a plurality of transfer structures arranged in the (n+1) th row to the (n+6a) row are arranged in a shape of “V”.

It should be noted that, when a plurality of transfer structures in the display substrate are arranged in the above-mentioned different ways, the data driver circuit needs to provide different data voltages for all light-emitting devices. No matter which arrangement of transfer structures in Table 1 or Table 2 is used in the display substrate, it is applicable to the method for driving the display substrate provided in the embodiments of the present disclosure.

As shown in FIG. 19, the method for driving the display substrate includes steps S510 to S530.

In step S510, a first sub-pixel region where a transfer structure is located among a plurality of pixel regions is obtained.

It is mentioned above that the first capacitance value of the parasitic capacitor in the first sub-pixel region is greater than the second capacitance value of the parasitic capacitor in the second sub-pixel region, resulting in the phenomenon that the brightness of the light-emitting device coupled to the pixel circuit in the first sub-pixel region is greater than the brightness of the light-emitting device coupled to the pixel circuit in the second sub-pixel region.

Therefore, in some examples, the data driver circuit may determine the light-emitting device with higher brightness by detecting the brightness of each light-emitting device, and then determine the first sub-pixel region where the pixel circuit coupled to the light-emitting device with higher brightness is located. In some other examples, the data driver circuit may determine the first sub-pixel region where the parasitic capacitor with a higher capacitance value is located by detecting the capacitance value of the parasitic capacitor of the data line in each sub-pixel region.

In addition, in some other examples, the data driver circuit may receive data information including preset first sub-pixel regions input by an operator, thereby determining the first sub-pixel region where the transfer structure is located.

In step S520, a grayscale value corresponding to the first sub-pixel region is reduced, and a voltage value of a data signal is increased based on the reduced grayscale value.

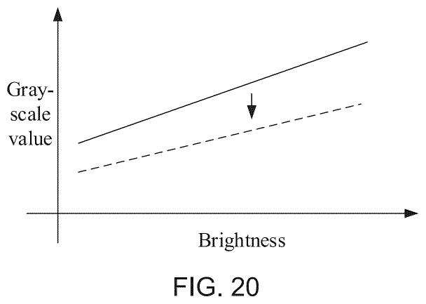

As shown in FIG. 20, the solid line in FIG. 20 is original grayscale values corresponding to the first sub-pixel region, and the dotted line in FIG. 20 is grayscale values corresponding to the first sub-pixel region after the original grayscale values are reduced. It can be understood that the original grayscale value of the first sub-pixel region is remapped to a lower grayscale value.

When the first sub-pixel regions are coupled to light-emitting devices of different colors, each first sub-pixel region may have the same mapping line or different mapping lines, which is not limited here. In addition, when the display substrate is in different brightness values, a single first sub-pixel region may correspond to the same mapping line, or may correspond to different mapping lines to meet the display requirements of different environments, which is not limited here.

The mapping line in FIG. 20 may only determine grayscale values corresponding to some brightness values, and the grayscale values corresponding to the remaining brightness values may be calculated based on a linear relationship.

In order to enable the first sub-pixel region to display based on the reduced grayscale value, the data driver circuit increases the voltage value of the data signal provided for the pixel circuit in the first sub-pixel region.

In step S530, a data signal with an increased voltage value is provided for each first sub-pixel region, to cause a light-emitting device corresponding to the first sub-pixel region to emit light.

The data driver circuit transmits the data signal with the increased voltage value to the pixel circuit in the first sub-pixel region, and then the pixel circuit in the first sub-pixel region provides the data signal for the corresponding light-emitting device, thereby reducing the brightness of the light-emitting device coupled to the pixel circuit in the first sub-pixel region. As a result, the brightness of the light-emitting device coupled to the pixel circuit in the first sub-pixel region is close to or even equal to the brightness of the light-emitting device coupled to the pixel circuit in the second sub-pixel region.

In summary, the method for driving the display substrate provided in the embodiments of the present disclosure may reduce the brightness of the light-emitting device coupled to the pixel circuit in the first sub-pixel region, so that the brightness of the light-emitting device coupled to the pixel circuit in the first sub-pixel region is close to or even equal to the brightness of the light-emitting device coupled to the pixel circuit in the second sub-pixel region. In this way, the uniformity of the light-emitting brightness of each light-emitting device on the display substrate may be improved, thereby improving the display effect of the display device.

As shown in FIG. 1, some embodiments of the present disclosure provide a display device 1000. The display device 1000 includes a display substrate 100 and an optical sensor 200. The display substrate 100 is the display substrate 100 as described in any of the above embodiments.

The display substrate 100 includes a display side 100A for emitting light and a back side 100B disposed opposite to the display side 100A. The optical sensor 200 is located on the back side 100B of the display substrate 100. A light-collecting side of the optical sensor 200 faces the back side 100B of the display substrate 100.

A light-collecting region of the optical sensor 200 at least partially coincides with the light-transmissive display region AA2 of the display substrate 100, so that the optical sensor 200 can acquire an image (e.g., a human face image, or a scene) at the display side 100A of the display substrate 100 through the light-transmissive display region AA2 of the display substrate 100.

In some examples, an orthogonal projection of an edge of the light-collecting region of the optical sensor 200 on the display substrate 100 substantially coincides with an edge of the light-transmissive display region AA2.

In some examples, the optical sensor 200 may be a camera.

Since the display device 1000 has the display substrate 100 provided in any of the above embodiments, the display device 1000 has the beneficial effects of the display substrate 100 provided in any of the above embodiments, and details are not repeated here.

The foregoing descriptions are merely specific implementation manners of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display substrate, comprising
a substrate including a display region and a peripheral region located on at least one side of the display region, the display region including a light-transmissive display region and a main display region located on at least one side of the light-transmissive display region;
a plurality of light-emitting devices, including a plurality of first light-emitting devices and a plurality of second light-emitting devices, wherein the plurality of first light-emitting devices are located in the light-transmissive display region, and the plurality of second light-emitting devices are located in the main display region;
a plurality of pixel circuits located in the main display region, wherein the plurality of pixel circuits include a plurality of first pixel circuits and a plurality of second pixel circuits, the plurality of first pixel circuits are coupled to the plurality of first light-emitting devices through a plurality of conductive lines, the plurality of second pixel circuits are coupled to the plurality of second light-emitting devices, and the plurality of second pixel circuits are arranged between the first pixel circuits at intervals;
a plurality of data lines, including a plurality of first data lines and a plurality of second data lines, wherein a first data line of the plurality of first data lines includes: a transfer signal line extending in a first direction, and a first data sub-line and a second data sub-line extending in a second direction; the transfer signal line is located between pixel circuits of the plurality of pixel circuits and is coupled to the first data sub-line and the second data sub-line, the second direction and the first direction intersecting; the first data sub-line is coupled to first pixel circuits of the plurality of first pixel circuits, and a second data line of the plurality of second data lines and the second data sub-line are coupled to second pixel circuits of the plurality of second pixel circuits; and
a plurality of control signal lines extending in the first direction, wherein the plurality of control signal lines are coupled to the plurality of first pixel circuits and the plurality of second pixel circuits;
wherein a parasitic capacitor between the first data line and a control signal line of the plurality of control signal lines has a first capacitance value, a parasitic capacitor between the second data line and the control signal line has a second capacitance value, and a difference between the first capacitance value and the second capacitance value is less than or equal to 0.15 fF.

2. The display substrate according to claim 1, wherein the first capacitance value and the second capacitance value are substantially equal.

3. The display substrate according to claim 1, wherein the main display region includes:
a plurality of sub-pixel regions, wherein the plurality of pixel circuits are respectively located in the plurality of sub-pixel regions; the plurality of sub-pixel regions include first sub-pixel regions and second sub-pixel regions; a first sub-pixel region of the first sub-pixel regions includes a transfer structure; and
the second data sub-line is coupled to the transfer signal line through the transfer structure.

4. The display substrate according to claim 3, wherein a second sub-pixel region of the second sub-pixel regions includes a dummy transfer structure; the dummy transfer structure is coupled to a part of a data line of the plurality of data lines in the second sub-pixel region and is separated from the transfer signal line.

5. The display substrate according to claim 4, wherein an area of an orthographic projection of the dummy transfer structure on the substrate is less than or substantially equal to an area of an orthographic projection of the transfer structure on the substrate.

6. The display substrate according to claim 4, wherein an orthographic projection of the transfer structure on the substrate at least partially coincides with an orthographic projection of the second data sub-line on the substrate; and
an orthographic projection of the dummy transfer structure on the substrate at least partially coincides with an orthographic projection of the second data line on the substrate.

7. The display substrate according to claim 4, wherein
the transfer structure includes a first transfer portion coupled to the second data sub-line, and a second transfer portion coupled to the first transfer portion and the transfer signal line;
the dummy transfer structure includes a third transfer portion coupled to the second data line, and a fourth transfer portion coupled to the third transfer portion and separated from the transfer signal line; and
the transfer signal line, the second transfer portion, and the fourth transfer portion are arranged in the same layer.

8. The display substrate according to claim 3, wherein an average size of a part of a data line of the plurality of data lines in a second sub-pixel region of the second sub-pixel regions in the first direction is greater than an average size of a part of a data line of the plurality of data lines in the first sub-pixel region in the first direction.

9. The display substrate according to claim 8, wherein the part of the data line in the second sub-pixel region includes a body portion extending in the second direction, and an extension portion extending from the body portion in the first direction; and
an orthographic projection of the extension portion on the substrate at least partially coincides with an orthographic projection of the control signal line on the substrate.

10. The display substrate according to claim 8, wherein a size of the extension portion in the second direction is greater than a size of the control signal line in the second direction.

11. The display substrate according to claim 3, wherein a distance between the transfer structure and the control signal line in the second direction is greater than or equal to 5 μm.

12. The display substrate according to claim 3, further comprising:
a plurality of initial lines, wherein a distance between at least one initial line of the plurality of initial lines and the transfer structure is less than or equal to 2 μm.

13. The display substrate according to claim 12, wherein an orthographic projection of the at least one initial line on the substrate at least partially overlaps with an orthographic projection of the transfer structure on the substrate.

14. The display substrate according to claim 3, wherein in the second direction, the transfer structure is located between the transfer signal line and the control signal line.

15. The display substrate according to claim 3, wherein a plurality of transfer structures are located on a side of the light-transmissive display region in the second direction, and the plurality of transfer structures are arranged in a shape of at least one “V”.

16. The display substrate according to claim 1, wherein the plurality of control signal lines include at least one of reset lines or gate lines.

17. The display substrate according to claim 1, further comprising:
a plurality of transparent signal lines extending in the first direction, wherein
an end of each transparent signal line of the plurality of transparent signal lines is coupled to a first pixel circuit, and another end of each transparent signal line is coupled to a first light-emitting device in the light-transmissive display region.

18. The display substrate according to claim 1, further comprising a multiplexer located in the peripheral region, wherein the multiplexer is coupled to at least two data lines among the plurality of data lines, and the multiplexer is configured to transmit a same data signal to different data lines of the at least two data lines in a time division manner.

19. A display device, comprising:
the display substrate according to claim 1; and
an optical sensor located on a back side of the display substrate, the back side of the display substrate being a side opposite to a display side of the display substrate, wherein
a light-collecting region of the optical sensor at least partially coincides with the light-transmissive display region of the display substrate.

20. The display device according to claim 19, wherein the first capacitance value and the second capacitance value are substantially equal.
